(19) United States
(12) Patent Application Publication
(10) Pub. No.: US 2005/0064679 A1
(43) Pub. Date: Mar. 24, 2005

(54) Consolidatable composite materials, articles of manufacture formed therefrom, and fabrication methods

(76) Inventors: Warren M. Farnworth, Nampa, ID (US); Alan G. Wood, Boise, ID (US)

Correspondence Address: TRASK BRITT, P.O. BOX 2550, SALT LAKE CITY, UT, 84110, US

(21) Appl. No.: 10/928,381

(22) Filed: Aug. 27, 2004

Related U.S. Application Data
(63) Continuation-in-part of application No. 10/666,742, filed on Sep. 19, 2003.

(51) Int. Cl. E21B 43/02; H01L 21/46; H01L 21/30

(52) U.S. Cl. 438/455

(57) ABSTRACT

A composite material includes an unconsolidated, consolidatable component and a physical modifier component. The consolidatable component is configured to be selectively consolidated to form an article, while the physical modifier component provides desired physical properties. The physical modifier component may be an unconsolidated material dispersed throughout the consolidatable component or a preformed matrix including interstices within which the consolidatable component may be introduced. The consolidatable component of the composite material may be selectively consolidated to fix the at least one physical component therein. Alternatively, the consolidatable component may be nonselectively consolidated, then regions thereof selectively removed. Methods for fabricating articles from such composite materials are also disclosed, as are systems that are configured for use in fabricating articles from such composite materials.

### CROSS-REFERENCE TO RELATED APPLICATION

This application is a continuation-in-part of U.S. application Ser. No. 10/666,742, pending.

### BACKGROUND OF THE INVENTION

1. Field of the Invention

The present invention relates to unconsolidated composite materials, which include at least one consolidatable component and one or more physical modifiers. The unconsolidated composite materials of the present invention are useful in a variety of programmed material consolidation processes and nonselective material consolidation processes that are used in layered manufacturing processes and which include one or more physical modifiers. In addition, the present invention relates to articles of manufacture that are at least partially formed from an at least partially consolidated composite material of the present invention, as well as to methods for fabricating articles of manufacture with a composite material of the present invention.

2. Background of Related Art

So-called “rapid prototyping processes,” such as stereolithography, selective layer sintering, layered object manufacturing, and the like, have experienced an increase in popularity over recent years. These processes facilitate the fabrication of prototypes and, in some cases, actual product, by use of programs (e.g., .stl programs, etc.) that use computer-aided drafting (CAD) data that would also be used to control machining equipment for fabricating molds or actual products, but without the expenses that are typically associated with machining, particularly when subsequent modification is required. Thus, when rapid prototyping processes are used, the consequential costs associated with refining the CAD data are typically much lower than when the CAD data is first used to machine a mold, product blank, or product.

More recently, the potential for using rapid prototyping-type processes in the mass production of articles of manufacture has been explored. In particular, rapid prototyping-type processes are useful in the manufacture of electronic components, including in the fabrication and packaging of semiconductor devices and semiconductor device components.

While such processes may be used to fabricate electrically conductive features of electronic components (e.g., semiconductor devices, semiconductor device assemblies, etc.), they may have an even greater potential for use in fabricating electrically insulative, or dielectric, structures that are to be used in conjunction with the fabrication of semiconductor devices, or that are to be formed on or assembled or packaged with semiconductor devices.

As this type of use for photopolymers does not involve prototyping but, rather, fabrication, manufacture, assembly, and packaging of devices that will actually be used, these techniques may also be referred to as material consolidation processes or, more specifically, as selective or programmed material consolidation processes.

The use of material consolidation processes in the fabrication, assembly, and packaging of semiconductor devices is desirable since they eliminate the need for expensive molds, decrease material wastage, and reduce post-fabrication processing (e.g., trimming of flash and runners from molded parts), among other reasons.

Photoimageable polymers, or “photopolymers,” have been subject to particular interest as materials that may be used with semiconductor devices. Among other reasons, photopolymers are desirable due to their dielectric properties, the high consolidation resolutions that may be achieved therewith when used in rapid prototyping processes, and their ability to be consolidated by techniques that are unlikely to damage the semiconductor devices upon or adjacent to which structures are to be fabricated. Despite these desirable features, photopolymers that have been used in rapid prototyping processes are somewhat incompatible for use with semiconductor devices. Specifically, the coefficients of thermal expansion (CTEs) of photopolymers typically differ significantly from the CTEs of the predominant materials of semiconductor devices. Consequently, when semiconductor devices are exposed to elevated temperatures (e.g., during burn-in processes, under normal operating conditions, etc.), the photopolymer expands to a different extent than semiconductor devices. Such differential expansion generates stresses in one or both of the semiconductor device and the photopolymer structure thereon, which stresses may cause delamination of the photopolymer structure from the semiconductor device or damage one or both of the photopolymer structure and the semiconductor device.

In addition to having CTEs that differ significantly from those of the predominant materials of semiconductor devices, photopolymers may also lack other desirable properties, including, without limitation, strength, heat stability, thermal conductivity, and the like.

Further, substantially pure photopolymers are typically very expensive, which hinders their desirability in the typically cost-conscious arts of semiconductor device fabrication, assembly, and packaging.

Accordingly, there are needs for consolidatable materials that may be used in selective consolidation processes and that are tailored to have desired physical characteristics, as well as for consolidatable materials that are compatible for use in semiconductor device fabrication, assembly, and packaging processes.

### SUMMARY OF THE INVENTION

The present invention includes an unconsolidated composite material that may be used in a variety of material consolidation processes, including programmed material consolidation processes, as well as articles of manufacture that are at least partially formed from the unconsolidated composite material and to methods for fabricating articles of manufacture from the unconsolidated composite material.

The unconsolidated composite material includes a consolidatable component which is configured to be consolidated by way of layered manufacturing processes, as well as at least one physical modifier, or filler, which imparts the composite material with one or more physical characteristics that are not provided by the consolidatable component.

In one embodiment of the unconsolidated composite material, the consolidatable component comprises a photoimageable polymer.

The one or more physical modifiers of the unconsolidated composite material may impart the unconsolidated composite material with a variety of properties or characteristics. For example, a physical modifier may impart the unconsolidated composite material with a desired rigidity, fracture resistance, structural integrity, coefficient of thermal expansion, thermal conductivity, or electrical conductivity.

Physical modifiers of the unconsolidated composite material may have any of a variety of configurations, including, without limitation, particles, fibers, nanotubes, nanospheres, or any other suitable configuration. The physical modifiers may be in an unconsolidated form, in which they are dispersed throughout the consolidatable component. Alternatively or additionally, the physical modifiers may be in the form of a matrix, such as a sheet with the consolidatable material at least partially filling at least some interstices between physical modifier units (e.g., particles, fibers, nanotubes, nanospheres, etc.).

Materials which are suitable for use as a physical modifier component of the present invention include, but are not limited to, silica (e.g., glass, silicon, etc.), alumina (i.e., ceramic), polymers, nitrides (e.g., boron nitride, silicon nitride, etc.), and carbon (e.g., carbon fibers, diamond grit, etc.).

Methods for making unconsolidated composite materials of the present invention are also within the scope of the present invention. By way of example only, one or more types of physical modifiers may be introduced into or mixed with a quantity of consolidatable material. Depending upon the type or types of physical modifiers employed, mixing may be facilitated by heating one or both of the consolidatable material and the physical modifier, by use of chemical blending agents or solvents, or by any other suitable technique. The resulting composite material may be used immediately or stored for transportation or later use.

In another aspect, the present invention includes methods for forming articles of manufacture from unconsolidated composite material. In one embodiment of a method of manufacture, consolidation processes are employed. The consolidation processes may be nonselective or selective. In selective material consolidation processes, such as programmed material consolidation processes, an unconsolidated composite material according to the present invention may be selectively consolidated by use of equipment under control of one or more computer programs, as known in the art, to fabricate a two- or three-dimensional structure. In stereolithography processes, which are an exemplary type of programmed material consolidation process, a layer is formed from the unconsolidated material and at least some of the layer is at least partially consolidated (e.g., in a selective manner). The layer formation and at least partial consolidation may be repeated at least once to form a structure which includes a plurality of at least partially superimposed, contiguous, mutually adhered layers of the unconsolidated composite material.

Another embodiment of a method of manufacture that incorporates teachings of the present invention includes providing a preformed matrix of physical modifier material, at least partially impregnating interstices of at least a portion of the preformed matrix with unconsolidated, consolidatable material. The consolidatable material within or on at least some of the preformed matrix is then at least partially consolidated. Such consolidation may be effected in a generalized fashion or in a selective, focused manner.

As unconsolidated composite materials that incorporate teachings of the present invention may necessitate modifications to programmable material consolidation systems, the modifications and systems including the modifications are also within the scope of the present invention.

Of course, articles of manufacture that are at least partially formed from unconsolidated composite material are also within the scope of the present invention. By way of nonlimiting example, an unconsolidated composite material that incorporates teachings of the present invention may be used to form features, such as protective structures, support structures, and the like, on semiconductor device components. As another example, teachings of the present invention may be used to form semiconductor device components themselves (e.g., interposers, circuit boards, etc.). An unconsolidated composite material of the present invention may also be used to fabricate various other articles, including, without limitation, parts for vehicles, electronic devices, models or prototypes, and the like.

Other features and advantages of the present invention will become apparent to those of skill in the art through consideration of the ensuing description, the accompanying drawings, and the appended claims.

### BRIEF DESCRIPTION OF THE DRAWINGS

In the drawings, which depict various features of exemplary embodiments of different aspects of the present invention:

FIG. 1 is a schematic representation of a process for mixing components, including a physical modifier component and a consolidatable component, of a composite material that incorporates teachings of the present invention;

FIG. 2 is a schematic representation of an exemplary system in which a composite material of the present invention may be used to fabricate articles of manufacture;

FIGS. 2A through 2D schematically depict an exemplary fabrication process that incorporates teachings of the present invention, in which an article is formed as a series of layers;

FIGS. 3A and 3B are schematic representations that show another exemplary fabrication process, in which the composite material is selectively exposed through a reticle;

FIG. 4 schematically depicts an at least partially consolidated composite material of the present invention;

FIG. 5 schematically illustrates a process for selectively removing regions of a structure formed from an at least partially consolidated composite material of the present invention;

FIGS. 6A through 6D and 7A through 7C show another embodiment of composite material of the present invention, including a preformed matrix of physical modifier material and an unconsolidated consolidatable material, as well as exemplary processes for forming articles from such a composite material.

### DETAILED DESCRIPTION

Exemplary materials that incorporate teachings of the present invention include consolidatable materials that are useful in layered manufacturing processes, such as photoimageable polymers that are useful in stereolithography processes. Since these materials may lack desired properties, such as sufficient rigidity, fracture resistance, toughness, a particular coefficient of thermal expansion, sufficient thermal conductivity, sufficient electrical conductivity, or the like, that may be desired, exemplary materials that incorporate teachings of the present invention also include at least one physical modifier.

Photopolymers that are useful as the consolidatable material component of composite materials that incorporate teachings of the present invention include, but are not limited to, the ACCURA® SI 40 Hc and AR materials, ACCURA® SI 40 ND material, and CIBATOOL SL 5170, SL 5210, SL 5530, and SL 7510 resins. The ACCURA® materials are available from 3D Systems, Inc., of Valencia, Calif., while the CIBATOOL resins are available from Ciba Specialty Chemicals Inc. of Bezel, Switzerland.

The photopolymer of a composite material of the present invention is formulated to be cured when exposed to a particular wavelength or range of wavelengths of electromagnetic radiation. For example, the exposure of the photopolymer to one or more wavelengths of electromagnetic radiation in the ultraviolet (UV) wavelength range of the spectrum of electromagnetic radiation may cause the photopolymer to at least partially cure, cross-link, or polymerize, resulting in a structure which is at least semisolid. Additionally, the photopolymer may be configured to further cure, cross-link, or polymerize when exposed to a particular threshold temperature.

The use of other types of consolidatable materials, including, without limitation, other photoimageable materials, two-part epoxies, heat curable materials, materials that may be sintered, and the like, in the inventive composite materials is also within the scope of the present invention.

By way of example, and not to limit the scope of the present invention, physical modifiers, or fillers, that may be used in composite materials that incorporate teachings of the present invention may be configured as particles of regular or irregular configuration (including, without limitation, spherical, ellipsoid, polyhedral, etc.), fibers of various lengths and cross-sectional sizes and shapes, nanotubes, nanospheres, in any other suitable configuration, or in any combination of configurations. The physical modifiers may be in an unconsolidated form, in which they are dispersed throughout the consolidatable component. Various sizes of the same physical modifier component may be included.

The physical modifiers may have dimensions that facilitate their introduction into recesses, voids, or other open features, or interstices, into which the composite material is to be introduced. As a nonlimiting example, the physical modifiers of a composite material of the present invention may have a maximum dimension of only about 5 μm or about 15 μm.

Alternatively, it may be desirable for physical modifiers of a composite material according to the present invention to have larger dimensions, such as in cases where the physical modifier imparts the composite material with a strength (including compressive, tensile, bending, torsional, etc.) or toughness that exceeds that of the photopolymer component of the composite material.

As another option, the configurations or dimensions of physical modifiers that are included in a composite material of the present invention may be selected so as to facilitate substantially uniform distribution thereof within the photopolymer component or another liquid component of the composite material, to minimize agglomeration of the physical modifiers, or for any other conceivable purpose.

Of course, the dimensions of the physical modifiers of a particular composite material that incorporates teachings of the present invention may not be critical.

Examples of physical modifiers or other fillers that may be used with any of the foregoing photopolymers include, but are not limited to, silica (i.e., glass, silicon), alumina (i.e., ceramic), nitrides (e.g., silicon nitride, boron nitride), polymers (e.g., poly(p-phenyleneterephtalamide), which is marketed under the trade name KEVLAR® by E.I. du Pont de Nemours & Company of Wilmington, Del.), elemental metals, and alloys.

Exemplary photoimageable polymers that are useful in stereolithography processes have CTEs of about 55×10⁻⁶/° C., whereas semiconductor devices have CTEs of less than 3×10⁻⁶/° C. When a silica filler material is included in such a photopolymer, with the mixture including about 50%, by weight, photoimageable polymer and about 50%, by weight, silica particles, the CTE of the resulting mixture, or composite material, is lowered significantly, to about 32×10⁻⁶/° C., which approaches the CTEs (e.g., about 18×10⁻⁶/° C. to about 22×10⁻⁶/° C.) of the organic polymers that have conventionally been used to package semiconductor devices.

When boron nitride (e.g., in powder or particulate form), diamond grit, ceramic, or a similar material is used in a composite material of the present invention as a physical modifier, it may impart the composite material with good thermal conductivity, which may be useful in fabricating heat sinks and other heat-conductive structures, as well as in providing a composite material with a CTE that more closely matches the CTE of a semiconductor device or other structure, relative to the CTE of the photopolymer component of the composite material, with which the composite material is to be used.

Physical modifiers may also increase or enhance the fracture toughness of fracture resistance (e.g., KEVLAR®), strength, rigidity, thermal properties (e.g., boron nitride), or structural integrity of the material (e.g., photopolymer, carbon fiber, etc.) within which they are mixed.

As another alternative, physical modifiers such as elemental metals or alloys may be used to tailor the electrical conductivity of a composite material that incorporates teachings of the present invention.

In addition to imparting a composite material of the present invention with one or more particular physical characteristics, physical modifiers contribute to the overall volume of a composite material and, thus, may effectively reduce the amount of expensive photopolymer needed for a particular application. By way of example only, physical modifiers may make up to about 80 percent or more (e.g., 30%, 50%, 80%, etc.) of the volume of a composite material that incorporates teachings of the present invention.

As the volume percent of the physical modifier component is increased in the photopolymer component of a composite material of the present invention, the thickness of a layer or quantity of the composite material that may be at least partially consolidated (e.g., in the case of a composite material that includes a photopolymer as the consolidatable component thereof, cured to a semisolid state) may decrease. For example, when any of the aforementioned photopolymers is used, it may be possible to at least partially consolidate selected regions of a layer of unconsolidated material, without physical modifier therein, having a thickness of as much as about 18×10⁻³ inches. When the physical modifier component makes up about 50 percent of the volume of the composite material, however, the maximum thickness of a layer of the composite material that may be selectively consolidated is only about 4.5×10⁻³ inches. Thus, the inclusion of too much physical modifier component may inhibit the ability of the consolidatable component (e.g., photopolymer) to consolidate (e.g., polymerize or cross-link, such as by reducing the transparency of a given quantity of the composite material). It may also be desirable to tailor the amount of physical modifier component in a composite material of the present invention to maintain a desired level of one or more structural characteristics (e.g., strength, toughness, appearance, etc.).

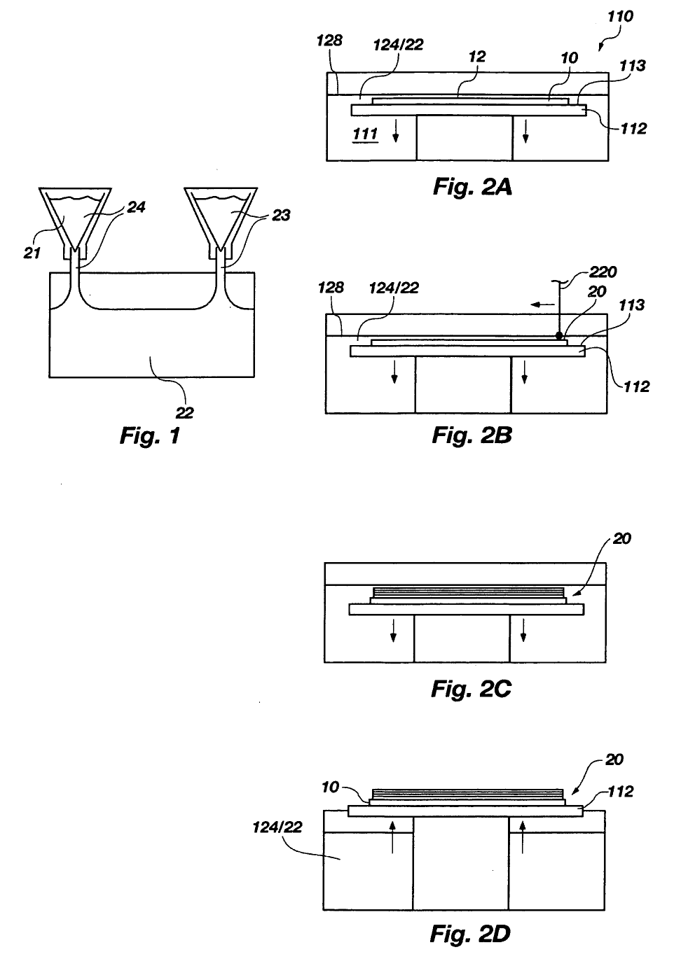

Referring now to FIG. 1, an exemplary process for forming an unconsolidated composite material 22 according to the present invention is depicted.

Initially, a physical modifier component 24 of unconsolidated composite material 22 may be filtered by techniques that are known in the art. By way of example only, a filter 21 of a type known in the art (e.g., a fine wire mesh filter, a polymeric filter, etc.) may be used to remove, or screen, particles that are undesirably large or undesirably small from particles having desired dimensions. Any combination of washing, rinsing, and filtration processes may also be used to remove any contaminants from physical modifier component 24. Of course, depending upon the type of filter used and the type of material or materials that make up physical modifier component 24, dispersal of physical modifier component in a liquid (e.g., a liquid which dissolves in or is otherwise compatible with the consolidatable component 23 (e.g., photopolymer) of unconsolidated composite material 22) and/or pressurization of physical modifier component 24, as known in the art, may be used to facilitate filtration.

If necessary or desired, the consolidatable component 23 of unconsolidated composite material 22 may be filtered prior to mixing or blending consolidatable component 23 with physical modifier component 24. Known filters and filtration processes that are suitable with the material employed as consolidatable component 23 may, of course, be used when filtration of photopolymer consolidatable component 23 is needed or desired.

Consolidatable component 23 and physical modifier component 24 may be mixed by any known, suitable process that will substantially homogeneously disperse or dissolve one of consolidatable component 23 and physical modifier component 24 throughout the other of these components. If unconsolidated composite material 22 includes more than one consolidatable component 23 or more than one physical modifier component 24, all of the components may be mixed together simultaneously or in a particular order, depending upon the properties of the various components, desired or undesired interactions between components that may result from a particular order of mixing, or other factors.

Mixing may be facilitated by elevating the temperature of the mixture or a component thereof, by addition and optional subsequent removal of blending agents or solvents for a component of the mixture, or by other suitable techniques, as known in the art.

It is desirable, although not necessary, that the environment in which mixing is effected, as well as the equipment that is used to effect mixing, be substantially free of contaminants.

Once consolidatable component 23 and physical modifier component 24 have been mixed to form unconsolidated composite material 22, unconsolidated composite material 22 may optionally be filtered or otherwise treated to remove any undesired contaminants, reaction products (between consolidatable component 23 or a portion thereof and physical modifier component 24 or a portion thereof), or the like. Filtration of unconsolidated composite material 22 may also be conducted to control (or further control) the size of any particles of physical modifier component 24 dispersed therethrough. Of course, known apparatus and processes may be used to filter or otherwise treat unconsolidated composite material 22.

Unconsolidated composite material 22 may be used immediately after the mixing and any desired treatment or filtration processes have been effected, or it may be stored for later use.

When unconsolidated composite material 22 is stored, it is currently preferred that it be stored in containers that will inhibit or prevent exposure thereof to electromagnetic radiation or other energy that will cause consolidatable component 23 thereof to consolidate (e.g., cure a photopolymer to polymerize, cross-link, or otherwise consolidate the same). Additionally, it is currently preferred that unconsolidated composite material 22 be stored at temperatures that will reduce or eliminate the tendency of consolidatable component 23 to consolidate (e.g., cause a photopolymer to polymerize, cross-link, or otherwise consolidate).

Physical modifier components 24, such as those that comprise particles, fibers, or the like, may not remain dissolved in, emulsified in, suspended in, or otherwise substantially homogenously dispersed throughout consolidatable component 23 during storage. Even some physical modifier components 24 that are dissolved or emulsified in a consolidatable component 23 may not remain substantially homogenously dispersed therethrough during storage. Accordingly, it may be desirable to mix, agitate, or otherwise substantially homogeneously disperse a physical modifier component 24 or a consolidatable component 23 throughout the remainder of unconsolidated composite material 22 periodically during storage thereof or following storage thereof.

It may also be desirable to remove (e.g., by filtration, treatment with solvents, etc.) any composite material that has become partially or fully polymerized, cross-linked, or otherwise consolidated from composite material that remains unconsolidated following storage and prior to use thereof.

Turning now to FIGS. 2 through 6C, exemplary consolidation and fabrication processes are described.

An exemplary programmable material consolidation process in which a composite material of the present invention may be used is schematically illustrated in FIGS. 2 through 2D and described with reference thereto.

In FIG. 2, an example of a programmable material consolidation system 100, which effects a type of programmed material consolidation process that employs selective irradiation of radiation-curable resin (e.g., with ultraviolet light, etc.), is schematically represented.

Programmable material consolidation system 100 includes a fabrication tank 110, as well as a material consolidation system 200, a machine vision system 300, a cleaning component 400, and a material reclamation system 500 that are associated with fabrication tank 110. The depicted programmable material consolidation system 100 also includes a substrate handling system 600, such as a rotary feed system or linear feed system available from Genmark Automation Inc. of Sunnyvale, Calif. Substrate handling system 600 is configured to move fabrication substrates 10 (e.g., semiconductor substrates) from one component system of programmable material consolidation system 100 to another. Features of one or more of the foregoing component systems may be associated with one or more controllers 700, such as computers, computer processors, or smaller groups of logic circuits, in such a way as to effect and orchestrate their operation in a desired manner.

Each controller 700 may comprise a computer or a computer processor, such as a so-called “microprocessor,” which may be programmed to effect a number of different functions. Alternatively, each controller 700 may be programmed to effect a specific set of related functions, or even a single function. Each controller 700 of programmable material consolidation system 100 may be associated with a single component system thereof or a plurality of component systems so as to synchronize the operation of the component systems relative to one another.

Fabrication tank 110 includes a chamber 111 that is configured to contain a support system 130. In turn, support system 130 is configured to carry one or more substrates 10 (e.g., semiconductor substrates).

Fabrication tank 110 may also have a reservoir 120 associated therewith. Reservoir 120 may be continuous with chamber 111. Alternatively, reservoir 120 may be separate from, but communicate with chamber 111 in such a way as to provide unconsolidated composite material 22, such as a composite material of the present invention (and which may, therefore, also be referred to herein as unconsolidated composite material 126), thereto. Reservoir 120 is configured to at least partially contain a volume 124 of unconsolidated composite material 22.

Reservoir 120 or another component associated with one or both of fabrication tank 110 and reservoir 120 may be configured to maintain a surface 128 of at least a portion of volume 124 located within chamber 111 at a substantially constant elevation relative to chamber 111.

Additionally, a homogenizer 122, which is configured to maintain the substantial homogeneity of unconsolidated composite material 22 (i.e., maintain the dispersion of physical modifier component 24 (FIG. 1) and consolidatable component 23 (FIG. 1) relative to one another), may be associated with one or both of fabrication tank 110 and reservoir 120. By way of example, homogenizer 122 may comprise an ultrasonic transducer of a known type (e.g., a piezoelectric transducer), which causes surfaces of fabrication tank 110 and/or reservoir 120 to vibrate. Vibrations in fabrication tank 110 or reservoir 120 are transmitted to unconsolidated composite material 22 therein, mixing the components of unconsolidated composite material 22. As another example, homogenizer 122 may comprise one or more rotatable blades, or mixing blades, and an associated motor of known type. Operation of homogenizer 122, including the intensity or degree of mixing effected thereby, may be controlled by a controller 700 in communication therewith.

Consolidation energy system 200 is associated with fabrication tank 110 in such a way as to direct consolidating energy 220 into chamber 111, toward at least areas of surface 128 of volume 124 of unconsolidated composite material 22 within reservoir 120 that are located over a support surface 113 of support system 130 of a substrate 10 (e.g., a semiconductor substrate) that has been positioned on support surface 113. Consolidation energy system 200 includes a source 210 of consolidating energy 220. Consolidating energy 220 may comprise, for example, electromagnetic radiation of a selected wavelength or a range of wavelengths (e.g., ultraviolet wavelengths, etc.), an electron beam, or other suitable energy for consolidating unconsolidated material 22. If consolidating energy 220 is focused, source 210 or a location control element 212 associated therewith (e.g., a set of galvanometers, including one for x-axis movement and another for y-axis movement) may be configured to direct, or position, consolidating energy 220 toward a plurality of desired areas of surface 128. Alternatively, if consolidating energy 220 remains relatively unfocused, it may be directed generally toward surface 128 from a single, fixed location or from a plurality of different locations. In any event, operation of source 210, as well as movement thereof, if any, may be effected under the direction of controller 700.

Programmable material consolidation system 100 may also include a machine vision system 300. Machine vision system 300 “recognizes” features on support surface 113 of support platen 112 of support system 130 in a manner known in the art and, thus, facilitates the direction of focused consolidating energy 220 toward desired locations of support surface 113 or a substrate 10 carried thereon. As with consolidation energy system 200, operation of machine vision system 300 may be proscribed by controller 700. If any portion of machine vision system 300, such as a camera 310 thereof, moves relative to chamber 111 of fabrication tank 110, that portion of machine vision system 300 may be positioned so as provide a clear path to all of the locations of surface 128 of volume 124 of unconsolidated composite material 22 that are located over each substrate 10 within chamber 111.

Optionally, one or both of consolidation energy system 200 (which may include a plurality of mirrors 214) and machine vision system 300 may be oriented and configured to operate in association with a plurality of fabrication tanks 110. Of course, one or more controllers 700 would be useful for coordinating the operation of consolidation energy system 200, machine vision system 300, and substrate handling system 600 relative to a plurality of fabrication tanks 110.

Cleaning component 400 of programmable material consolidation system 100 may also operate under the direction of controller 700. Cleaning component 400 of programmable material consolidation system 100 may be continuous with a chamber 111 of fabrication tank 110 or positioned adjacent to fabrication tank 110. If cleaning component 400 is continuous with chamber 111, any unconsolidated material 22 that remains on a fabricated structure 20 or a substrate 10 (see FIGS. 2A through 2D), if any, on or adjacent to which an object has been fabricated may be removed therefrom prior to fabrication of another object within chamber 111.

If cleaning component 400 is positioned adjacent to fabrication tank 110, residual unconsolidated composite material 22 may be removed from a fabricated object or substrate 10 as the same is removed from chamber 111. Alternatively, any unconsolidated material 22 remaining on a fabricated object 20 or substrate 10 may be removed therefrom after the same has been removed from chamber 111, in which case the cleaning process may occur as another substrate 10 is positioned within chamber 111 or fabrication of another object within chamber 111 is initiated.

Material reclamation system 500 is used to collect excess unconsolidated material 22 that has been removed from a fabricated structure (not shown) or a substrate 10 by cleaning system 400, then return the excess unconsolidated composite material 22 to reservoir 120 associated with fabrication tank 110.

In use, controller 700, under control of suitable programming (e.g., stereolithography (.stl) programming when programmable material consolidation system 100 is a stereolithography system, computer-aided drafting (CAD) programming, etc.), may orchestrate operation of various components of programmable material consolidation system 100 to fabricate structures from a composite material that incorporates teachings of the present invention.

FIGS. 2A through 2D depict an example of the manner in which programmable material consolidation system 100 (FIG. 2) may be used to fabricate a structure 20 from an unconsolidated composite material 22 of the present invention. As depicted, structure 20 may be fabricated on or proximate to a substrate 10, although fabrication of structure 20 with an unconsolidated composite material 22 of the present invention may be effected without a substrate.

With reference to FIG. 2A, substrate 10, such as a semiconductor device structure (e.g., a full or partial semiconductor wafer or other substrate carrying a plurality of semiconductor devices, a carrier substrate or collection of yet-to-be singulated carrier substrates, one or more device-substrate or device-leadframe assemblies, etc.), is positioned on a support surface 113 of a support platen 112 within chamber 111 of fabrication tank 110 of programmable material consolidation system 100 (FIG. 2). As depicted, substrate 10 may be submerged within volume 124 of unconsolidated composite material 22 so that unconsolidated composite material 22 covers and fills all of the features that are located at an exposed surface 12 of substrate 10.

Next, as shown in FIG. 2B, support platen 112 is raised such that support surface 113 of support platen 112 or surface 12 of a substrate 10 (FIG. 2A) on support platen 112 is brought to a desired elevation relative to surface 128 of volume 124 (e.g., below or at about the same level as, or coplanar with surface 128). Unconsolidated composite material 22 at desired locations of surface 128 are then at least partially selectively consolidated (e.g., by directing a laser or other focused consolidating energy 220 toward the desired locations) to initiate the formation of structure 20. This process may be effected once, if structure 20 comprises a single material layer, or repeated multiple times, lowering support platen 112 in multiple increments until structure 20 includes the desired number of superimposed, contiguous, mutually adhered layers of material. Of course, any change in the density of unconsolidated composite material 22 upon consolidation thereof may be considered in determining the distance that support platen 112 is lowered with each incremental lowering and, thus, the distance support surface 113 of support platen 112 is submerged beneath surface 128 of volume 124 of unconsolidated composite material 22 with each increment.

As illustrated in FIG. 2C, these processes may be repeated a number of times until a structure 20 has been completely formed.

Following the fabrication of a structure 20, platen 112 may be raised such that at least structure 20 and, optionally, a substrate 10 on or adjacent to which structure 20 has been fabricated, are removed from volume 124 of unconsolidated composite material 22, as shown in FIG. 2D. Thereafter, structure 20 and, optionally, substrate 10 may be cleaned, as known in the art.

Of course, programmable material consolidation systems that operate differently than that depicted in FIGS. 2 through 2D may also be used to form structures from an unconsolidated composite material 22 without departing from the scope of the present invention. For example, and not to limit the scope of the present invention, systems selectively deposit unconsolidated material 22 concurrently with or before consolidating the same, and not necessarily as layers, may also be used in accordance with teachings of the present invention. Exemplary systems of this type are available from Objet Geometries Ltd. of Rehovot, Israel, as the EDEN330 and QUADRATEMPO systems.

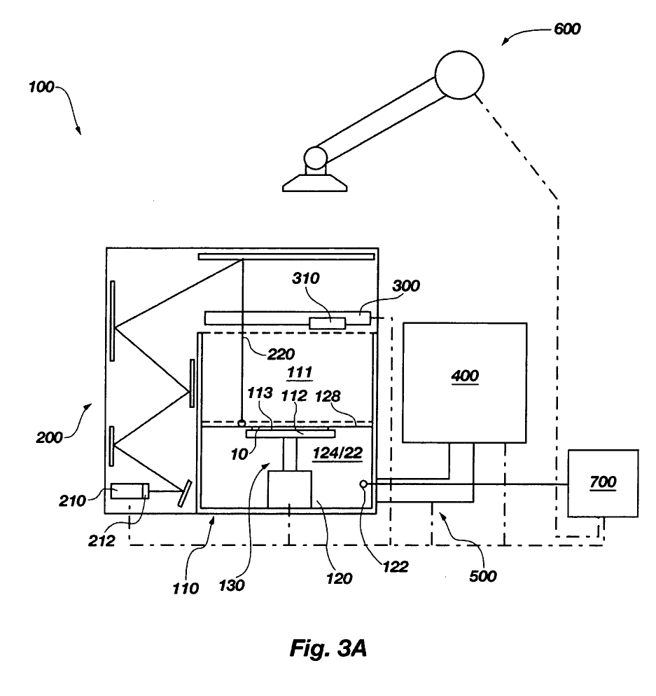

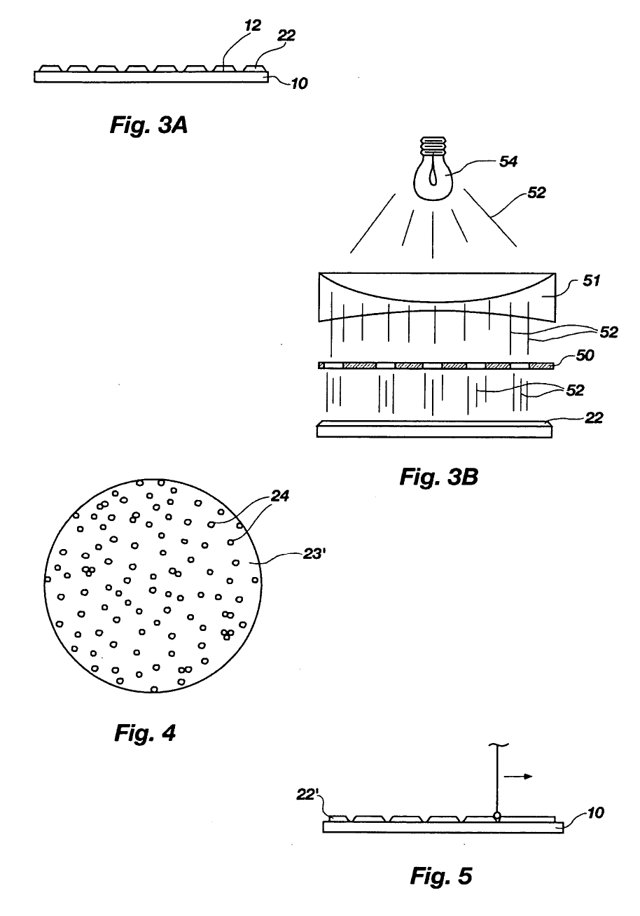

Another exemplary process for forming one or more structures from an unconsolidated composite material 22 according to the present invention is schematically depicted in FIGS. 3A and 3B. As shown in FIG. 3A, unconsolidated composite material 22 may be applied to a surface 12 of a substrate 10 by known processes (e.g., by spin-on processes, screen printing, spray-on processes, use of a doctor blade, or otherwise, as known in the art). If a desired patter is formed from unconsolidated composite material 22 as it is applied, it may be nonselectively exposed to radiation (e.g., consolidating radiation). If, in the alternative, an unpatterned layer of unconsolidated composite material 22 is formed, desired regions of unconsolidated composite material 22 may be selectively exposed, for example, through the depicted reticle 50, to one or more suitable wavelengths of radiation 52 from a radiation source 54 and through a collimating lens 51, as in known photolithography processes, as illustrated in FIG. 3B. Thereafter, the exposed regions may be developed with a chemical or chemicals, which may also be referred to as “developing agents,” if necessary to consolidate the composite material that has been selectively exposed to radiation 52.

Upon consolidating or at least partially consolidating consolidatable component 23 (FIG. 1) to at least a semisolid state, the consolidated component 23′ exhibits a matrix with at least one physical modifier component 24 dispersed therethrough, as depicted in FIG. 4.

As another example, depicted in FIG. 5, a layer of unconsolidated composite material 22 (see FIG. 3A) may be nonselectively consolidated to an at least semisolid state. Thereafter, selected regions of the at least partially consolidated composite material 22′ may be ablated, such as by exposure to a wavelength of electromagnetic radiation or other type of energy that will ablate a consolidated component 23′ or physical modifier component 24 (FIG. 4) of consolidated composite material 22′. For example, 355 nm ultraviolet light may be used to ablate composite material 22′. Ablation may, by way of nonlimiting example, be effected with a laser micromachining system, such as the XISE 200 or XISE 300D available from XSiL Ltd. of Dublin, Ireland, or excimer laser ablation equipment available from Tamarack Scientific Co., Inc., of Corona, Calif., as models 330, 410, and 500. With returned reference to FIG. 3B, such selective ablation may be effected through a reticle 50. Alternatively, focused energy (e.g., a laser beam of an appropriate wavelength, an electron beam, etc.) may be used to selectively ablate at least partially consolidated composite material 22′. In either event, it is desirable that the ablating radiation be focused at a point within consolidated composite material 22′ that will not damage the underlying substrate 10, or be tailored to ablate at least one component of consolidated composite material 22′ without damaging the underlying substrate 10.

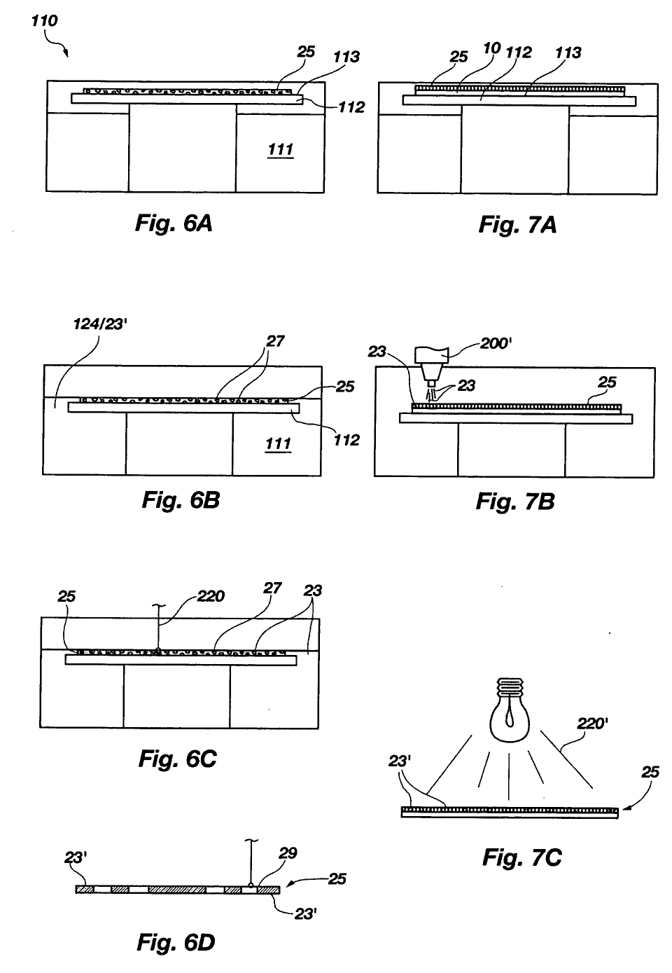

Turning now to FIGS. 6A through 6E and FIGS. 7A through 7C, another embodiment of a method of manufacture that incorporates teachings of the present invention is depicted, as is another embodiment of the inventive composite material.

In FIG. 6A, a preformed matrix 25 of physical modifier material, such as the illustrated planar structure or sheet, is provided. As shown, preformed matrix 25 is positioned upon a support surface 113 of a support platen 112. While support platen 112 is depicted as being located within a chamber 111 of a fabrication tank 110 of a programmable material consolidation system 100 (FIG. 2), it should be understood that the method of manufacture described hereinafter need not be effected in a programmable material consolidation system.

Alternatively, as shown in FIG. 7A, preformed matrix 25 may be positioned over a substrate 10 that has been positioned on support surface 113 of support platen 112.

Next, as depicted in FIG. 6B, interstices 27, or voids, within preformed matrix 25 are infiltrated with any suitable unconsolidated consolidatable material 23″ (e.g., the depicted photopolymer), as known in the art. As shown, support platen 112 is effectively immersed within a volume 124 of consolidatable material 23″ held within fabrication tank 111. Preformed matrix 25 may comprise a grid, a woven or nonwoven sheet, a perforated sheet, a porous material, or the like. Interstices or voids 27 of preformed matrix 25 may be of visible or microscropic dimensions, regular or irregular shapes and in a predetermined pattern or randomly distributed.

FIG. 7B illustrates a variation of the act shown in FIG. 5B, in which unconsolidated consolidatable material 23 is selectively or nonselectively dispensed onto preformed matrix 25 by known techniques. In the depicted example, a material dispense head 200′, such as that used in the aforementioned Objet systems, may be used to selectively apply consolidatable material 23 to various regions of preformed matrix 25. As another alternative, a material dispense needle of a known type may be used to selectively or nonselectively apply consolidatable material 23 to preformed matrix 25.

The unconsolidated consolidatable material 23 that has been introduced into interstices 27 of matrix 25 may be at least partially consolidated (e.g., cured, cross-linked, sintered, or otherwise consolidated) during or after its introduction into interstices 27, as shown in FIGS. 6C and 7C. Such consolidation of unconsolidated consolidatable material 23 may be effected by any known, suitable process. For example, as depicted in FIG. 6C, consolidatable material 23 (e.g., photopolymer) may be selectively consolidated with focused consolidating energy 220 (e.g., a UV laser beam). As another example, illustrated in FIG. 7C, selectively dispensed consolidatable material 23 (e.g., photopolymer) may be consolidated in a more general fashion, with unfocused consolidating energy 220′ (e.g., UV light).

Following initial consolidation of the previously unconsolidated material, excess consolidatable material 23 (e.g., photopolymer), if any (see FIG. 6C), may be removed from interstices 27 of preformed matrix 25 (e.g., by washing, rinsing, etc.) and further consolidation may be effected. As a nonlimiting example, when a photopolymer is used, the at least partially consolidated photopolymer may be exposed to unfocused consolidating energy (e.g., unfocused UV light, as shown in FIG. 7C, an elevated temperature, etc.,) to further cure, or cross-link the same.

Once the material 23 (e.g., consolidated photopolymer) has been sufficiently consolidated (e.g., cured, cross-linked, sintered, etc.) regions 29 of preformed matrix 25 that are exposed beyond consolidated material 23′ may be removed, as illustrated in FIG. 6D. Exemplary means for removing exposed regions 29 include, but are not limited to, physical removal (e.g., cutting (e.g., laser, mechanical, etc.), degrading (e.g., with heat), or otherwise physically removing exposed regions 29 from consolidated material 23′), chemical removal (e.g., with etchants, solvents, or other chemicals that will selectively remove exposed regions 29 without substantially removing consolidated material 23′ or regions of matrix 25 within consolidated material 23′), or other suitable removal processes.

Of course, if desired, exposed regions 29 of preformed matrix 25 need not be removed.

The resulting article of manufacture is shown in FIG. 6D.

Although the foregoing description contains many specifics, these should not be construed as limiting the scope of the present invention, but merely as providing illustrations of some of the presently preferred embodiments. Similarly, other embodiments may be devised without departing from the spirit or scope of the present invention. Features from different embodiments may be employed in combination. The scope of the invention is, therefore, indicated and limited only by the appended claims and their legal equivalents rather than by the foregoing description. All additions, deletions and modifications to the invention as disclosed herein which fall within the meaning and scope of the claims are to be embraced thereby.

1. A material for use in stereolithographic fabrication processes, comprising:
a photoimageable component; and
at least one filler material disposed through the photoimageable component.

2. The material of claim 1, wherein the photoimageable component comprises an ultraviolet radiation-curable material.

3. The material of claim 1, wherein the photoimageable component comprises a photoimageable polymer.

4. The material of claim 1, wherein at least a portion of the at least one filler material is particulate.

5. The material of claim 1, wherein at least a portion of the at least one filler material is fibrous.

6. The material of claim 1, wherein the at least one filler material comprises nanotubes.

7. The material of claim 1, wherein the at least one filler material comprises nanospheres.

8. The material of claim 1, wherein the at least one filler material comprises a sheet and the photoimageable component fills interstices of the sheet.

9. The material of claim 1, wherein the at least one filler material comprises at least about 80% of a volume of the material.

10. The material of claim 1, wherein the at least one filler material comprises at least about 50% of a volume of the material.

11. The material of claim 1, wherein the at least one filler material comprises at least about 30% of a volume of the material.

12. The material of claim 1, wherein the at least one filler material is present in an amount in which the material retains sufficient transparency to be useful in a stereolithographic fabrication process.

13. The material of claim 1, wherein the at least one filler material comprises a polymer.

14. The material of claim 13, wherein the polymer comprises poly(p-phenyleneterephtalamide).

15. The material of claim 1, wherein the at least one filler material comprises a nitride.

16. The material of claim 15, wherein the nitride comprises boron nitride.

17. The material of claim 1, wherein the at least one filler material comprises a silica.

18. The material of claim 1, wherein the at least one filler material comprises an alumina.

19. The material of claim 1, wherein the at least one filler material imparts the material when at least partially consolidated with a greater fracture resistance than the fracture resistance of the photoimageable component alone when at least partially consolidated to the same state.

20. The material of claim 1, wherein the at least one filler material imparts the material when at least partially consolidated with a lower coefficient of thermal expansion than the coefficient of thermal expansion of the photoimageable component alone when at least partially consolidated to the same state.

21. The material of claim 1, wherein the at least one filler material imparts the material when at least partially consolidated with a better thermal conductivity than the thermal conductivity of the photoimageable component alone when at least partially consolidated to the same state.

22. The material of claim 1, wherein a mixture of the photoimageable component and the at least one filler material when at least partially consolidated has a greater structural integrity than a structural integrity of the photoimageable material alone when at least partially consolidated to the same state.

23. The material of claim 1, wherein the at least one filler material comprises a plurality of different types of filler materials.

24. The material of claim 1, wherein the photoimageable component is in an unconsolidated state.

25. The material of claim 1, wherein the photoimageable component is in an at least partially consolidated state.

26. An article of manufacture, comprising a material including a consolidated photoimageable material and at least one filler extending through at least a portion of the photoimageable material.

27. The article of manufacture of claim 26, wherein the photoimageable material comprises a photoimageable polymer.

28. The article of manufacture of claim 26, wherein the photoimageable material comprises an ultraviolet radiation-curable material.

29. The article of manufacture of claim 26, wherein at least a portion of the at least one filler is particulate.

30. The article of manufacture of claim 26, wherein at least a portion of the at least one filler is fibrous.

31. The article of manufacture of claim 26, wherein the at least one filler comprises nanotubes.

32. The article of manufacture of claim 26, wherein the at least one filler comprises nanospheres.

33. The article of manufacture of claim 26, wherein the at least one filler comprises a sheet and the photoimageable material fills interstices of the sheet.

34. The article of manufacture of claim 26, wherein the at least one filler comprises at least about 80% of a volume of the material.

35. The article of manufacture of claim 26, wherein the at least one filler comprises at least about 50% of a volume of the material.

36. The article of manufacture of claim 26, wherein the at least one filler comprises at least about 30% of a volume of the material.

37. The article of manufacture of claim 26, wherein the at least one filler comprises a polymer.

38. The article of manufacture of claim 37, wherein the polymer comprises poly(p-phenyleneterephtalamide).

39. The article of manufacture of claim 26, wherein the at least one filler comprises a nitride.

40. The article of manufacture of claim 39, wherein the nitride comprises boron nitride.

41. The article of manufacture of claim 26, wherein the at least one filler comprises a silica.

42. The article of manufacture of claim 26, wherein the at least one filler comprises an alumina.

43. The article of manufacture of claim 26, wherein the at least one filler imparts the material when at least partially consolidated with a greater fracture resistance than the fracture resistance of the photoimageable component alone when at least partially consolidated to the same state.

44. The article of manufacture of claim 26, wherein the at least one filler imparts the material when at least partially consolidated with a lower coefficient of thermal expansion than the coefficient of thermal expansion of the photoimageable component alone when at least partially consolidated to the same state.

45. The article of manufacture of claim 26, wherein the at least one filler imparts the material when at least partially consolidated with a better thermal conductivity than the thermal conductivity of the photoimageable component alone when at least partially consolidated to the same state.

46. The article of manufacture of claim 26, wherein a mixture of the photoimageable component and the at least one filler when at least partially consolidated has a greater structural integrity than a structural integrity of the photoimageable material alone when at least partially consolidated to the same state.

47. The article of manufacture of claim 26, wherein the at least one filler comprises a plurality of different types of fillers.

48. A semiconductor device component, comprising:
a substrate;
at least one protective structure on at least a portion of a surface of the substrate, the at least one protective structure comprising a material including:
a photoimageable component; and
at least one filler.

49. The semiconductor device component of claim 48, wherein the substrate includes at least one of a semiconductor die, a semiconductor substrate, an interposer, a carrier substrate, and a test substrate.

50. The semiconductor device component of claim 48, wherein the at least one filler of at least a portion of the at least one protective structure comprises a sheet of material including the photoimageable component within interstices thereof.

51. The semiconductor device component of claim 50, wherein the sheet comprises fibers of poly p-phenyleneterephtalamide).

52. The semiconductor device component of claim 50, wherein the sheet substantially covers a major surface of the substrate.

53. The semiconductor device component of claim 50, wherein the sheet structurally supports the substrate.

54. The semiconductor device component of claim 48, wherein the at least one filler comprises at least one of particles, fibers, nanotubes, and nanospheres.

55. The semiconductor device component of claim 48, wherein the at least one filler comprises at least one of a silica, an alumina, a polymer, and a nitride.

56. The semiconductor device component of claim 48, wherein the at least one filler comprises poly(p-phenyleneterephtalamide).

57. The semiconductor device component of claim 48, wherein the at least one filler comprises boron nitride.

58. The semiconductor device component of claim 48, wherein the at least one filler facilitates heat transfer away from the substrate.

59. The semiconductor device component of claim 48, wherein the at least one filler imparts the at least one protective structure with a coefficient of thermal expansion that more closely matches a coefficient of thermal expansion of a material of the substrate than a coefficient of thermal expansion of the photoimageable material.

60. The semiconductor device component of claim 48, wherein the photoimageable material comprises a photoimageable polymer.

61. The semiconductor device component of claim 48, wherein the photoimageable material comprises an ultraviolet radiation-curable material.

62. A fabrication method, comprising:
forming a layer comprising a photoimageable material and at least one filler extending through at least a portion of the photoimageable material; and
at least partially consolidating at least some of the photoimageable material in the layer.

63. The fabrication method of claim 62, wherein forming the layer comprises forming the layer with the at least one filler dispersed throughout the photoimageable material.

64. The fabrication method of claim 62, wherein forming the layer comprises forming the photoimageable material filling interstices of a sheet of the at least one filler.

65. The fabrication method of claim 62, wherein at least partially consolidating comprises consolidating the photoimageable material in selected regions of the layer.

66. The fabrication method of claim 65, wherein at least partially consolidating comprises stereolithographically consolidating the photoimageable material in the selected regions.

67. The fabrication method of claim 62, further comprising:
substantially consolidating the at least some of the photoimageable material.

68. The fabrication method of claim 67, wherein substantially consolidating includes heating the photoimageable material.

69. The fabrication method of claim 62, further comprising:
repeating the forming and the at least partially consolidating at least once.

70. The fabrication method of claim 62, further comprising:
patterning at least the photoimageable material following the at least partially consolidating.

71. The fabrication method of claim 70, wherein patterning comprises ablating at least the photoimageable material.

72. The fabrication method of claim 71, wherein ablating comprises exposing selected regions of the photoimageable material to ultraviolet radiation.

73. The fabrication method of claim 71, wherein ablating is effected through a reticle.

74. The fabrication method of claim 71, wherein ablating is selectively effected with focused radiation.

75. A method for forming a structure on a semiconductor device component, comprising:
forming a layer comprising photoimageable material and at least one filler extending through at least a portion of the photoimageable material on at least a portion of the semiconductor device component; and
at least partially consolidating at least some of the photoimageable material in the layer.

76. The method of claim 75, wherein forming comprises placing a sheet of the at least one filler on at least the portion of the semiconductor device component.

77. The method of claim 76, wherein forming further comprises infiltrating interstices of the sheet with the photoimageable material.

78. The method of claim 76, wherein at least partially consolidating comprises at least partially consolidating substantially all of the photoimageable material on the sheet.

79. The method of claim 78, wherein at least partially consolidating comprises nonselectively exposing the photoimageable material to radiation of at least one appropriate wavelength.

80. The method of claim 78, wherein at least partially consolidating comprises heating at least the photoimageable material.

81. The method of claim 75, wherein forming the layer comprises forming a layer of unconsolidated photoimageable material with the at least one filler dispersed therethrough on at least the portion of the semiconductor device component.

82. The method of claim 76, wherein at least partially consolidating comprises at least partially consolidating selected regions of the photoimageable material.

83. The method of claim 82, wherein at least partially consolidating is effected with a beam of focused radiation.

84. The method of claim 75, further comprising:
repeating forming and at least partially consolidating at least once.

85. The method of claim 75, further comprising:
patterning at least the photoimageable material following at least partially consolidating.

86. The method of claim 85, wherein patterning comprises ablating at least the photoimageable material.

87. The method of claim 86, wherein ablating comprises exposing selected regions of the photoimageable material to ultraviolet radiation.

88. The method of claim 86, wherein ablating is effected through a reticle.

89. The method of claim 86, wherein ablating is selectively effected with focused radiation.

90. A method for forming a consolidatable material, comprising:
providing a quantity of unconsolidated, photoimageable material;
mixing at least one filler material into the quantity of unconsolidated, photoimageable material; and
dispersing at least one of the at least one filler and the quantity of unconsolidated, photoimageable material throughout the other.

91. The method of claim 90, wherein mixing comprises introducing a fibrous material into the quantity of unconsolidated, photoimageable material.

92. The method of claim 91, further comprising:
reducing lengths of at least some fibers of the fibrous material prior to introducing the fibrous material into the quantity of unconsolidated, photoimageable material.

93. The method of claim 92, wherein reducing comprises laser ablating the at least some fibers.

94. A method for fabricating an article of manufacture, comprising:
providing a substrate comprising a matrix;
introducing a consolidatable material into interstices of the matrix; and
at least partially consolidating the consolidated material at selected locations of the substrate.

95. The method of claim 94, wherein providing comprises positioning the substrate on another object.

96. The method of claim 94, wherein providing comprises providing a substantially planar substrate.

97. The method of claim 94, wherein providing comprises a fibrous substrate.

98. The method of claim 94, further comprising:
removing remaining unconsolidated material from the substrate following at least partially consolidating the unconsolidated material.

99. The method of claim 98, further comprising:
removing portions of the substrate with interstices that do not include consolidated material.

100. The method of claim 99, wherein removing comprises at least one of cutting and laser ablating the portions of the substrate.

101. A programmable material consolidation system, comprising:
a reservoir for storing a composite consolidatable material;
a homogenizer for improving or maintaining a substantially consistent dispersal of components of the composite consolidatable material relative to one another;
a system for introducing the composite consolidatable material onto a support platen or a substrate; and
a system for selectively consolidating the composite consolidatable material.

102. The programmable material consolidation system of claim 101, wherein the system for introducing comprises a fabrication tank within which a volume of the composite consolidatable material is contained.

103. The programmable material consolidation system of claim 101, wherein the system for selectively consolidating comprises a system for introducing a focused beam of consolidating energy onto a surface of the composite consolidatable material.

104. The programmable material consolidation system of claim 101, wherein the system for selectively consolidating comprises a reticle and an unfocussed source of consolidating energy.
